(19) United States
(12) Patent Application Publication
(10) Pub. No.: US 2026/0173645 A1
(43) Pub. Date: Jun. 18, 2026

(54) ORGANIC LIGHT-EMITTING ELEMENT AND DISPLAY DEVICE INCLUDING THE SAME

(71) Applicant: LG Display Co., Ltd., Seoul (KR)

(72) Inventors: Daehee Han, Incheon (KR); GyuHyeong Han, Seoul (KR); Eonho Cha, Bucheon-si (KR)

(73) Assignee: LG Display Co., Ltd., Seoul (KR)

(21) Appl. No.: 19/369,272

(22) Filed: Oct. 26, 2025

(30) Foreign Application Priority Data
Dec. 17, 2024 (KR) 10-2024-0187919

(51) Int. Cl. H10K 50/15; H10K 59/122

(52) U.S. Cl. CPC H10K 50/15; H10K 59/122

(57) ABSTRACT

Provided are an organic light-emitting element and a display device including the same. The organic light-emitting element includes a substrate. The organic light-emitting element further includes a first electrode disposed on the substrate. The organic light-emitting element further includes a hole auxiliary layer disposed on the first electrode. The organic light-emitting element further includes at least one organic light-emitting layer disposed on the hole auxiliary layer. The organic light-emitting element further includes an electron auxiliary layer disposed on the organic light-emitting layer. The organic light-emitting element further includes at least one binder disposed in the organic light-emitting layer and including a functional group secondarily bonded to the organic light-emitting layer. The organic light-emitting element further includes a second electrode disposed on the electron auxiliary layer.

### CROSS-REFERENCE TO RELATED APPLICATION

This application claims the priority of Korean Patent Application No. 10-2024-0187919, filed on Dec. 17, 2024, in the Korean Intellectual Property Office, the disclosure of which is incorporated herein by reference.

### BACKGROUND

### Field

The present specification relates to an organic light-emitting element and a display device including the same.

### Description of the Related Art

Display devices, which visually display electrical information signals, are being rapidly developed in accordance with the entry into the information era. Various studies are being continuously conducted to develop a variety of display devices which are thin and lightweight, consume low power, and have improved performance.

As the representative display devices, there may be a liquid crystal display device (LCD), a field emission display device (FED), an electrowetting display device (EWD), an organic light-emitting display device (OLED), and the like.

An electroluminescent display device, as the representative organic light-emitting display device, refers to a display device that autonomously emits light. Unlike a liquid crystal display device, the electroluminescent display device does not require a separate light source and thus may be manufactured as a lightweight, thin display device.

In addition, the electroluminescent display device is advantageous in terms of power consumption because the electroluminescent display device operates at a low voltage. Further, the electroluminescent display device is expected to be adopted in various fields because the electroluminescent display device is also excellent in implementation of colors, response speeds, viewing angles, and contrast ratios (CRs).

### SUMMARY

An object to be achieved by the present disclosure is to provide an organic light-emitting element with improved luminous properties, and a display device including the same.

Another object to be achieved by the present disclosure is to provide an organic light-emitting element capable of operating at a high temperature and having thermal stability, and a display device including the same.

Still another object to be achieved by the present disclosure is to provide an organic light-emitting element capable of suppressing an excessive light leakage current (LLC), and a display device including the same.

Objects of the present disclosure are not limited to the above-mentioned objects, and other objects, which are not mentioned above, can be clearly understood by those skilled in the art from the following descriptions.

According to an aspect of the present disclosure, there is provided an organic light-emitting element. The organic light-emitting element includes a substrate. The organic light-emitting element further includes a first electrode disposed on the substrate. The organic light-emitting element further includes a hole auxiliary layer disposed on the first electrode. The organic light-emitting element further includes at least one organic light-emitting layer disposed on the hole auxiliary layer. The organic light-emitting element further includes an electron auxiliary layer disposed on the organic light-emitting layer. The organic light-emitting element further includes at least one binder disposed in the organic light-emitting layer and including a functional group secondarily bonded to the organic light-emitting layer. The organic light-emitting element further includes a second electrode disposed on the electron auxiliary layer.

According to another aspect of the present disclosure, there is provided a display device. The display device includes a substrate including a display area, the display area including a plurality of subpixels. The display device further includes an organic light-emitting element disposed on the substrate in the display area and including a first electrode, an organic light-emitting part disposed on the first electrode, and a second electrode disposed on the organic light-emitting part. The display device further includes a bank disposed on the substrate and including an opening configured to expose the first electrode. The display device further includes at least one binder disposed in the opening and including a functional group secondarily bonded to a light-emitting layer of the organic light-emitting part.

Other detailed matters of various example embodiments are included in the detailed description and the drawings.

According to one or more example embodiments of the present disclosure, at least one binder may be disposed in the organic light-emitting part, thereby improving luminous properties by suppressing initial excessive aggregation during deposition of each layer of the organic light-emitting part.

According to one or more example embodiments of the present disclosure, the binder including the functional group capable of secondary bonding (or hydrogen bonding) with the material of the organic light-emitting layer may be disposed in the organic light-emitting part, thereby increasing a glass transition temperature (Tg) of the organic light-emitting layer.

According to one or more example embodiments of the present disclosure, the high thermal stability of the organic light-emitting layer may be ensured, thereby enabling a stable operation at a high temperature.

According to one or more example embodiments of the present disclosure, the organic binder including the non-conductive material may be disposed in the organic light-emitting layer, thereby inhibiting an excessive light leakage current from flowing along the boundary between the organic light-emitting elements.

According to one or more example embodiments of the present disclosure, the binder may be disposed to further protrude than the organic light-emitting part, and the top surface of the electrode on the organic light-emitting part may be implemented not to be flat, thereby changing a path of light emitted from the organic light-emitting part and suppressing a deterioration in light extraction efficiency.

According to one or more example embodiments of the present disclosure, the luminous efficiency of the organic light-emitting element may be improved, such that the organic light-emitting element may operate with low power consumption.

The effects according to example embodiments of the present disclosure are not limited to the above-mentioned effects, and various additional effects can be attained from the present disclosure.

### BRIEF DESCRIPTION OF DRAWINGS

The accompanying drawings, which are included to provide a further understanding of the present disclosure and are incorporated in and constitute a part of this application, illustrate embodiments of the present disclosure and together with the description serve to explain various principles of the disclosure. The above and other aspects, features and other advantages of the present disclosure will be more clearly understood from the following detailed description taken in conjunction with the accompanying drawings, in which:

FIG. 1 is a block diagram of a display device according to an example embodiment of the present specification;

FIG. 2 is a drive circuit diagram of a subpixel of the display device according to an example embodiment of the present specification;

FIG. 3 is a cross-sectional view taken along line I-I′ in FIG. 1;

FIG. 4 is a cross-sectional view of an organic light-emitting element according to an example embodiment of the present specification;

FIG. 5A is a top plan view for explaining an example of an arrangement structure of a binder of the organic light-emitting element according to an example embodiment of the present specification;

FIG. 5B is a top plan view for explaining another example of the arrangement structure of the binder of the organic light-emitting element according to an example embodiment of the present specification;

FIG. 5C is a top plan view for explaining still another example of the arrangement structure of the binder of the organic light-emitting element according to an example embodiment of the present specification;

FIG. 6 is a cross-sectional view of an organic light-emitting element according to another example embodiment of the present specification;

FIG. 7 is a cross-sectional view of an organic light-emitting element according to still another example embodiment of the present specification;

FIG. 8 is a cross-sectional view of an organic light-emitting element according to yet another example embodiment of the present specification;

FIG. 9 is a cross-sectional view of an organic light-emitting element according to still yet another example embodiment of the present specification;

FIG. 10 is a cross-sectional view of an organic light-emitting element according to a further example embodiment of the present specification;

FIG. 11 is a cross-sectional view of an organic light-emitting element according to another further example embodiment of the present specification; and

FIG. 12 is a cross-sectional view of a subpixel of a display device according to another example embodiment of the present specification.

### DETAILED DESCRIPTION

Advantages and characteristics of the present disclosure and a method of achieving the advantages and characteristics will be clear by referring to example embodiments described below in detail together with the accompanying drawings. However, the present disclosure is not limited to the example embodiments disclosed herein but can be implemented in various other forms. The example embodiments are provided by way of example only so that those skilled in the art can more fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of,” if used herein, are generally intended to allow other components to be added unless the terms are used with a more specific term like “only.” Any references to singular may include plural, and vice versa, unless expressly stated otherwise.

Components are to be interpreted to include an ordinary error range even if not expressly stated.

Where the position relation between two parts is described using the terms such as “on,” “above,” “below,” and “next,” one or more other parts may be positioned between the two parts unless the terms are used with a more specific term like “immediately” or “directly.”

Where an element or layer is described as being disposed “on” another element or layer, another layer or another element may be interposed directly on the other element or therebetween.

Although the terms “first,” “second,” and the like may be used for describing various components, these components are not confined by these terms. These terms are merely used for referring to one component separately from the other components. Therefore, a first component to be mentioned below may be a second component, and vice versa, in a technical concept of the present disclosure.

Like reference numerals generally denote like elements throughout the specification, unless otherwise specified.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to example embodiments of the present disclosure will be described in detail with reference to accompanying drawings.

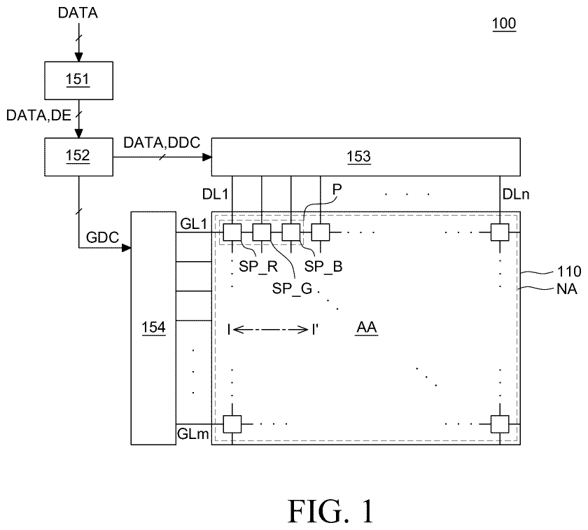

FIG. 1 is a block diagram of a display device according to an example embodiment of the present specification.

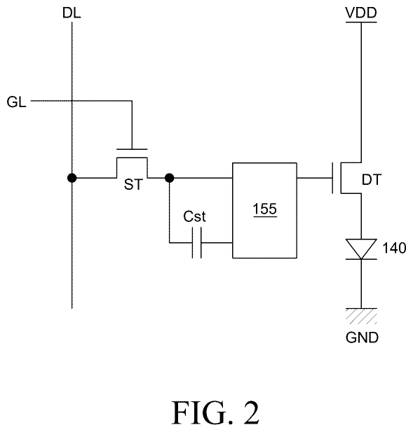

FIG. 2 is a drive circuit diagram of a subpixel of the display device according to an example embodiment of the present specification.

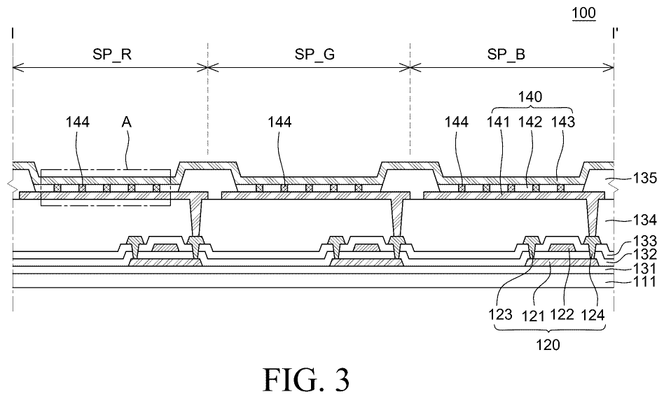

FIG. 3 is a cross-sectional view taken along line I-I′ in FIG. 1.

With reference to FIG. 1, a display device 100 according to an example embodiment of the present specification may include an image processor 151, a timing controller 152, a data driver 153, a gate driver 154. and a display panel 110.

The image processor 151 may output a data signal DATA, a data enable signal DE, and the like supplied from the outside. The image processor 151 may output one or more of a vertical synchronizing signal, a horizontal synchronizing signal, and a clock signal in addition to the data enable signal DE.

The timing controller 152 receives the data signal DATA in addition to the data enable signal DE or the driving signals including the vertical synchronizing signal, the horizontal synchronizing signal, and the clock signal from the image processor 151. On the basis of the driving signal, the timing controller 152 may output a gate timing control signal GDC for controlling an operation timing of the gate driver 154 and output a data timing control signal DDC for controlling an operation timing of the data driver 153.

In response to the data timing control signal DDC supplied from the timing controller 152, the data driver 153 may sample and latch the data signal DATA supplied from the timing controller 152, convert the data signal DATA into a gamma reference voltage, and output the gamma reference voltage. The data driver 153 may output the data signal DATA through data lines DL1 to DLn. The data driver 153 may be provided in the form of an integrated circuit (IC).

The gate driver 154 may output the gate signal while shifting a level of the gate voltage in response to the gate timing control signal GDC supplied from the timing controller 152. The gate driver 154 may output the gate signal through gate lines GL1 to GLm. The gate driver 154 may be provided in the form of an integrated circuit (IC) or formed on the display panel 110 in a gate-in-panel (GIP) manner.

Meanwhile, the data driver 153 and the gate driver 154 may each be implemented as one or more integrated circuits. The data driver 153 and the gate driver 154 may each be implemented as a chip-on-glass (COG) type, a chip-on-film (COF) type, or a tape carrier package (TCP) type in a standpoint related to the electrical connection with the display panel 110.

The display panel 110 includes a plurality of pixels P, and the plurality of pixels P each display images while emitting light in response to the data signal and the gate signal supplied from the data driver 153 and the gate driver 154.

With reference to FIGS. 1 and 3 together, in the display device 100 according to the embodiment of the present specification, the display panel 110 includes a substrate 111 on which the plurality of pixels P are disposed. In this case, one pixel P may include a plurality of subpixels SP_R, SP_G, and SP_B. FIG. 1 illustrates an example in which one pixel P includes three subpixels SP_R, SP_G, and SP_B configured to emit light beams with different colors. For example, in the display device 100 according to the embodiment of the present specification, one pixel P may include a subpixel SP_R configured to emit red light, a subpixel SP_G configured to emit green light, and a subpixel SP_B configured to emit blue light. However, the number of subpixels included in one pixel P is not limited thereto. For example, one pixel P may further include a subpixel configured to emit white light in addition to the subpixels configured to emit red light, green light, and blue light.

The substrate 111 is configured to support various constituent elements included in the display device 100. The substrate 111 may be made of an insulating material. In addition, the substrate 111 may be made of a flexible material that may be bent. In addition, the substrate 111 may be made of a transparent material. For example, the substrate 111 may be made of a plastic material such as polyimide. However, the present specification is not limited thereto.

A plurality of gate lines GL, which extend in a first direction, and a plurality of data lines DL, which extend in a second direction different from the first direction, are disposed on the substrate 111 and intersect one another. In this case, the pixels P are defined at points on the substrate 111 at which the plurality of gate lines GL and the plurality of data lines DL intersect.

With reference to FIGS. 1 and 3 together, an area, in which the plurality of pixels P configured to implement images on the substrate 111 of the display panel 110 are disposed, may be defined as a display area AA, and an area, which is disposed at an outer periphery of the display area AA and does not have the plurality of pixels P, may be defined as a non-display area NA.

A display part for displaying images may be formed in the display area AA, and a circuit part for operating the display part may be formed in the display area AA. For example, the display device 100 according to the embodiment of the present specification may be an organic light-emitting display device. In this case, the display part may include an organic light-emitting element. That is, the display part may include an anode, a light-emitting layer on the anode, and a cathode on the light-emitting layer. For example, the organic light-emitting layer may include a hole transporting layer, a hole injection layer, an organic light-emitting layer, an electron injection layer, and an electron transporting layer. However, the present specification is not limited thereto.

The circuit part may include various transistors, capacitors, and lines for operating the light-emitting element. Specifically, the circuit part may include various constituent elements such as a driving transistor, a switching transistor, a storage capacitor, a gate line, and a data line. However, the present specification is not limited thereto.

For example, the subpixels SP_R, SP-G, and SP_B of the display device 100 according to the embodiment of the present specification may each include a switching transistor, a driving transistor, a capacitor, and a light-emitting element.

With reference to FIG. 2, the subpixels SP_R, SP_G, and SP_B of the display device 100 according to the embodiment of the present specification may each include a switching transistor ST, a driving transistor DT, a compensating circuit 155, and a light-emitting element 140. In addition, the subpixels may each include a line or the like connected to a power source for operating the pixel.

The light-emitting element 140 may operate to emit light in accordance with a drive current produced by the driving transistor DT.

The switching transistor ST may perform a switching operation so that the data signal supplied through the data line DL is stored, as a data voltage, in a capacitor Cst in response to the gate signal supplied through the gate line GL.

The driving transistor DT may operate such that a predetermined drive current flows between a high-potential power line VDD and a low-potential power line GND while corresponding to the data voltage stored in the capacitor Cst.

The example has been described above in which the drive circuit of each of the subpixels SP_R, SP_G, and SP_B has a 2T (Transistor) 1C (Capacitor) structure including one switching transistor, one driving transistor, and one capacitor in the display device 100 according to the embodiment of the present specification.

In another example, the drive circuit of each of the subpixels SP_R, SP_G, and SP_B of the display device 100 according to the embodiment of the present specification may further include the compensating circuit 155. The compensating circuit 155 is a circuit for compensating for a threshold voltage or the like of the driving transistor. The compensating circuit 155 may include one or more compensating thin-film transistors and one or more compensating capacitors. In this case, the configurations and structures of the compensating thin-film transistor and the compensating capacitor are not limited thereto but may be variously implemented in accordance with compensation methods. For example, in case that the compensating circuit is added to the subpixel, the pixel may have various structures such as 3T1C, 4T2C, 5T2C, 6T1C, 6T2C, 7T1C, or 7T2C.

With reference to FIG. 1, the non-display area NA is an area in which no image is displayed. The non-display area NA is an area in which various lines, circuits, and the like for operating the display part disposed in the display area AA are disposed.

The non-display area NA may be defined as an area that surrounds the display area AA. However, the present specification is not limited thereto. For example, the non-display area NA may be defined as an area extending from the display area AA. In addition, the non-display area NA may also be defined as extending from a plurality of sides of the display area AA.

The non-display area NA may include a pad area formed to receive a data driving signal or the like from an external power source or transmit or receive a touch signal to or from the external power source. An external module, e.g., drive ICs, such as a data driver integrated circuit (IC) or a gate driver IC, may be positioned in the pad area.

The drive ICs disposed in the pad area may be connected to a plurality of lines and connected to the plurality of data lines DL or the plurality of gate lines GL, which are disposed in the display area AA, through the plurality of lines. That is, the drive ICs disposed in the pad area may be respectively and electrically connected to the plurality of pixels P.

The display device including the organic light-emitting element according to an example embodiment of the present specification will be described with reference to FIG. 3. FIG. 3 illustrates that the light-emitting display device 100 according to an example embodiment of the present specification operates in a top emission manner. However, the present specification is not limited thereto.

The display device 100 according to an example embodiment of the present specification includes the substrate 111, a buffer layer 131, thin-film transistors 120, planarization layers 134, banks 135, and organic light-emitting elements 140.

The substrate 111 serves to support and protect the constituent elements of the display device disposed above the substrate 111. The substrate 111 may be a rigid substrate or a flexible substrate that may be bent, folded, or rolled.

In case that the substrate 111 is made of a plastic material having flexibility, the substrate 111 may be made of polyimide (PI), for example. In case that the substrate 111 is made of polyimide (PI), a process of manufacturing the display device 100 may be performed in a state in which a support substrate made of glass is disposed below the substrate 111, and the support substrate may be released after the process of manufacturing the display device 100 is completed.

In case that the substrate 111 is made of polyimide (PI), the substrate 111 may be made of double polyimide (PI) materials to suppress a situation in which moisture penetrates the substrate 111, which is made of polyimide (PI), and permeates into the thin-film transistor 120 or the light-emitting element 140, and the performance of the display device 100 deteriorates. The substrate 111 may further include an inorganic film disposed between the double polyimide (PI) materials. Therefore, electric charges charged on polyimide (PI) disposed at the lower side may be blocked, thereby improving reliability of a product.

The buffer layer 131 is disposed on the substrate 111. The buffer layer 131 may be a multi-buffer layer including a plurality of inorganic films.

A semiconductor layer 121 of the thin-film transistor 120 may be disposed on the buffer layer 131, and the buffer layer 131 may be configured to protect the semiconductor layer 121 and increase an interface bonding force of the semiconductor layer 121.

The display device 100 according to the embodiment of the present specification may further include a metal layer disposed below any one of the plurality of layers of the buffer layer 131. The metal layer may serve as a light shield.

The thin-film transistor 120 is disposed on the buffer layer 131.

The thin-film transistor 120 may include the semiconductor layer 121, a gate electrode 122, a source electrode 123, and a drain electrode 124. In accordance with design of the pixel drive circuit, the source electrode 123 may be a drain electrode, and the drain electrode 124 may be a source electrode.

The semiconductor layer 121 may include a channel area configured to overlap the gate electrode 122, and first and second areas positioned at two opposite sides of the channel area and respectively connected to the source electrode 123 and the drain electrode 124.

A gate insulation layer 132 is disposed on the semiconductor layer 121 and insulates the semiconductor layer 121 and the gate electrode 122.

The gate insulation layer 132 may be formed on the entire surface of the display area AA while covering the semiconductor layer 121. The gate insulation layer 132 may be made of an inorganic insulating material, e.g., silicon dioxide (SiO₂), silicon nitride (SiNx), silicon oxynitride (SiO_{N}), or a multilayer thereof. However, the present specification is not limited thereto.

The gate electrode 122 is disposed on the gate insulation layer 132, and the gate electrode 122 and the semiconductor layer 121 overlap each other with the gate insulation layer 132 interposed therebetween.

For example, the gate electrode 122 may be configured as a single layer or multilayer made of any one of molybdenum (Mo), aluminum (Al), chromium (Cr), gold (Au), titanium (Ti), nickel (Ni), neodymium (Nd), and copper (Cu) or an alloy thereof. However, the present specification is not limited thereto.

An interlayer insulation layer 133 is disposed on the gate electrode 122.

The interlayer insulation layer 133 may be formed on the entire surface of the display area AA while covering the gate electrode 122. The interlayer insulation layer 133 may be made of the same inorganic insulating material, e.g., silicon dioxide (SiO₂), silicon nitride (SiNx), silicon oxynitride (SiON), or a multilayer thereof as the gate insulation layer 132. However, the present specification is not limited thereto.

The source electrode 123 and the drain electrode 124 are disposed on the interlayer insulation layer 133 and spaced apart from each other.

The source electrode 123 and the drain electrode 124 are electrically connected to the semiconductor layer 121 through contact holes formed through the interlayer insulation layer 133 and the gate insulation layer 132.

FIG. 3 illustrates an example in which the thin-film transistor 120 is formed in a top gate manner in which the gate electrode 122 is positioned above the semiconductor layer 121. However, the present specification is not limited thereto. That is, the thin-film transistor 120 may be formed in a bottom gate manner in which the gate electrode 122 is positioned below the semiconductor layer 121. Alternatively, the thin-film transistor 120 may be formed in a double gate manner in which two gate electrodes 122 are positioned above and below the semiconductor layer 121 respectively.

In addition, FIG. 3 illustrates one thin-film transistor 120 corresponding to one subpixel. However, the number and type of the thin-film transistor 120 corresponding to one subpixel are not limited thereto. For example, FIG. 3 illustrates only the driving transistor, which serves to operate the organic light-emitting element 140, as the thin-film transistor 120. However, the subpixel may further include the switching transistor corresponding to the light-emitting element.

The planarization layer 134 may be disposed on the thin-film transistor 120 and disposed on the entire surface of the display area AA. The organic light-emitting element 140 and the bank 135 are disposed on the planarization layer 134. A first electrode 141 of the organic light-emitting element 140 is connected to the drain electrode 124 of the thin-film transistor 120 through a contact hole formed through the planarization layer 134.

The planarization layers 134 may be configured to flatly arrange the first electrodes 141 of the light-emitting elements 140 separated by the banks 135. For example, the planarization layer 134 may be made of resin such as photo acrylic and polyimide (PI).

The light-emitting element 140 disposed on the planarization layer 134 may be configured by sequentially stacking the first electrode 141, an organic light-emitting part 142, and binders 144, which are disposed in the organic light-emitting part 142, and a second electrode 143.

An example will be described in which the display device 100 according to the embodiment of the present specification is a top emission type display device in which emitted light propagates toward a position above the substrate 111 on which the light-emitting element 140 is disposed. In this case, the first electrode (i.e., anode electrode) 141 of the light-emitting element 140 may further include a transparent conductive layer, and a reflective layer on the transparent conductive layer. For example, the transparent conductive layer may be made of transparent conductive oxide such as ITO or IZO. For example, the reflective layer may be made of silver (Ag), aluminum (Al), gold (Au), molybdenum (Mo), tungsten (W), chromium (Cr), or an alloy thereof.

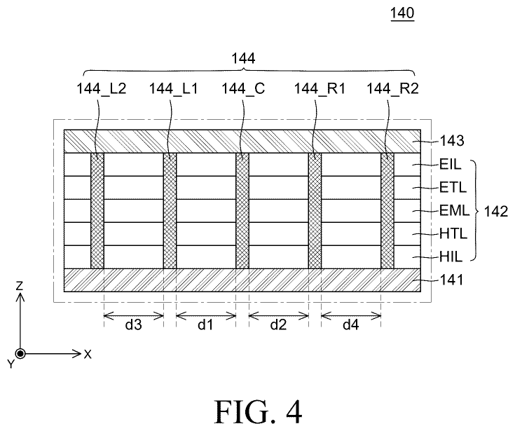

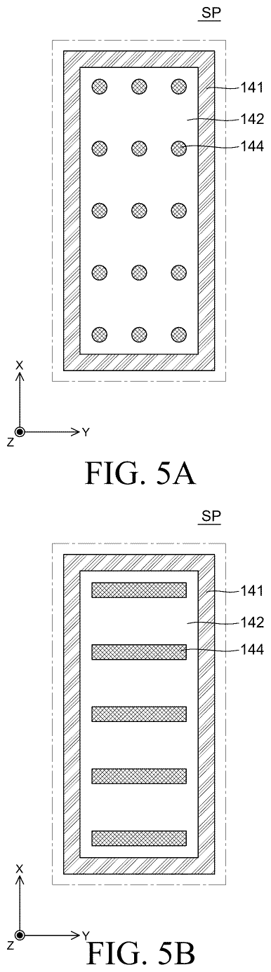

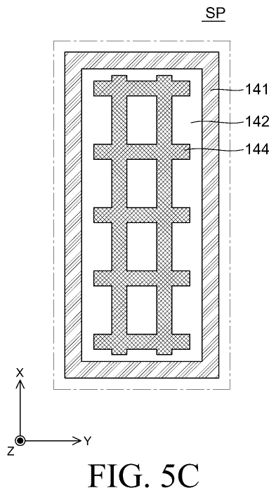

The configuration and structure of the organic light-emitting element 140 of the display device 100 according to the embodiment of the present specification will be described below in detail with reference to FIGS. 4 to 5C.

In addition, the banks 135 are disposed on the planarization layer 134 and separate the plurality of subpixels SP_R, SP_G, and SP_B.

The bank 135 includes an opening portion provided in an area (i.e., light-emitting area) that overlaps the light-emitting element 140 of each of the subpixels SP_R, SP_G, and SP_B, such that a part of the first electrode 141 of the light-emitting element 140 is exposed.

Meanwhile, in the display device 100 according to the embodiment of the present specification, an encapsulation layer may be disposed on the light-emitting element 140 and the bank 135. The encapsulation layer may be disposed on the entire surface of the display area AA while covering the light-emitting element 140. In the display device 100 according to the embodiment of the present specification, the organic light-emitting part 142 of the light-emitting element 140 may be positioned in the opening portion of the bank 135, and the second electrode 143 of the light-emitting element 140 may be positioned in the opening portion of the bank 135, disposed outside the opening portion, and configured to cover an upper portion of the bank 135. However, the second electrode 143 of the light-emitting element 140 may have a structure disposed outside the opening portion so as to overlap only a part of the bank 135. In this case, the encapsulation layer may be disposed to directly adjoin the bank 135 as well as the light-emitting element 140.

In the display device 100 according to the embodiment of the present specification, a color filter layer may be further disposed on the encapsulation layer.

The color filter layer may include a light-blocking layer and a color filter.

The light-blocking layer overlaps the bank 135 and includes a plurality of opening portions that overlaps the opening portion of the bank 135. For example, a width of the light-blocking layer may be smaller than a width of the bank 135, and a width of the opening portion of the light-blocking layer may be larger than a width of the opening portion of the bank 135 that overlaps the opening portion of the light-blocking layer.

The light-blocking layer suppresses a situation in which external light introduced from the outside is reflected by the line or the like of the display device 100 and visually recognized by a viewer's eyes. The light-blocking layer may be positioned to overlap an edge of the area (i.e., light-emitting area) in which the light-emitting element is disposed, and the light-blocking layer may absorb the introduced external light and reduce a degree to which the external light enters the light-emitting area. For example, the light-blocking layer may be a black matrix including a black material.

The color filter may be positioned on the light-blocking layer, most of the color filter may overlap the opening portion of the light-blocking layer, and a part of the color filter may overlap the light-blocking layer. For example, the color filter may be configured to have a shape that fills the opening portion of the light-blocking layer.

The color filter reduces a degree to which external light introduced from the outside is introduced into the bank 135 or the like, reflected, and visually recognized. Because the color filter does not completely block light, it is possible to inhibit reflected external light from being visually recognized without reducing efficiency of the light emitted from the light-emitting layer of the organic light-emitting element 140.

In case that the plurality of subpixels of the display device 100 according to the embodiment of the present specification include the organic light-emitting element 140 configured to output white light, the color filters respectively corresponding to the plurality of subpixels SP_R, SP_G, and SP_B may be a red color filter configured to convert white light into red light, a blue color filter configured to convert white light into blue light, and a green color filter configured to convert white light into green light.

Hereinafter, the organic light-emitting element 140 of the display device 100 according to an example embodiment of the present specification will be described in detail with reference to FIGS. 4 and 5A.

FIG. 4 is a cross-sectional view of the organic light-emitting element according to the embodiment of the present specification.

With reference to FIG. 4, the organic light-emitting element 140 according to the embodiment of the present specification includes the first and second electrodes 141 and 143 configured to face each other, the organic light-emitting part 142 positioned between the first electrode 141 and the second electrode 143, and the binders 144 disposed in the organic light-emitting part 142.

The first electrode 141 may be made of an electrically conductive material with a comparatively large work function value. The first electrode 141 may be an anode. The first electrode 141 may include a transparent conductive layer, and a reflective layer on the transparent conductive layer. For example, the first electrode 141 may be made of indium-tin-oxide (ITO), indium-zinc-oxide (IZO), indium-tin-zinc-oxide (ITZO), indium-copper-oxide (ICO), or aluminum: zinc oxide (Al: ZnO; AZO). However, the present specification is not limited thereto. For example, the reflective layer may be made of silver (Ag), aluminum (Al), gold (Au), molybdenum (Mo), tungsten (W), chromium (Cr), an alloy thereof, or the like.

The second electrode 143 may be made of an electrically conductive material with a comparatively small work function value. The second electrode 143 may be a cathode. For example, the second electrode 143 may be made of aluminum (Al), magnesium (Mg), calcium (Ca), silver (Ag), ytterbium (Yb), or an alloy thereof.

The organic light-emitting part 142 includes a hole auxiliary layer including a hole injection layer HIL and a hole transporting layer HTL, an organic light-emitting layer EML including a light-emitting material layer, and an electron auxiliary layer including an electron transporting layer ETL and an electron injection layer EIL. However, the present specification is not limited thereto.

The hole injection layer HIL is positioned between the first electrode 141 and the organic light-emitting layer EML, and the hole transporting layer HTL is positioned between the hole injection layer HIL and the organic light-emitting layer EML.

The hole injection layer HIL improves interface properties between the first electrode 141, which is made of an inorganic material, and the hole transporting layer HTL made of an organic material. The hole injection layer HIL is disposed on the first electrode 141 and serves to facilitate the injection of holes.

For example, the hole injection layer HIL may be made of any one material selected from a group consisting of 4,4′,4′ tris(3methylphenylphenylamino)triphenylamine (MTDATA), copper phthalocyanine (CuPc), tris(4-carbazoyl-9-yl-phenyl)amine (TCTA), N,N′-diphenyl-N,N′-bis(1-naphthyl)-1,1'-biphenyl-4,4′ diamine (NPB; NPD), 1,4,5,8,9,11-exaazatriphenylenehexacarbonitrile (HATCN), 1,3,5-tris[4-(diphenylamino)phenyl]benzene (TDAPB), poly(3,4-ethylenedioxythiphene), polystyrene sulfonate (PEDOT/PSS), 2,3,5,6-tetrafluoro-7,7,8,8-tetracyanoquinodimethane (F4TCNQ), and/or N-(biphenyl-4-yl)-9,9-dimethyl-N-(4-(9-phenyl-9H-carbazol-3-yl)phenyl)-9H-fluoren-2-amine.

The hole transporting layer HTL is positioned adjacent to the organic light-emitting layer EML, and the hole transporting layer HTL is disposed on the hole injection layer HIL and serves to smoothly transmit holes to the organic light-emitting layer EML.

The hole transporting layer HTL may be formed by doping a hole transporting host with an organic compound. The hole transporting host applicable to the hole transporting layer HTL may be a material having high triplet energy. For example, the hole transporting host may be a monoamine-based organic material substituted with a fused aromatic ring and having excellent thermal stability. However, the present specification is not limited thereto.

For example, the monoamine-based organic material applicable as the hole transporting host of the hole transporting layer HTL may be selected from a group consisting of TCTA, tris(trifluorovinyl ether)-tris(4-carbazoyl-9-ylphenyl)amine (TFV-TCTA), tris[4-(diethylamino)phenyl]amine, N-(biphenyl-4-yl)-9,9-dimethyl-N-(4-(9-phenyl-9H-carbazol-3-yl)phenyl)-9H-fluoren-2-amine, tri-p-tolylamine, and/or N-[1,1′-biphenyl]-4-yl-9,9-dimethyl-N-[4-(9-phenyl-9H-carbazol-3-yl)phenyl]amine. However, the present specification is not limited thereto.

The light-emitting material layer of the organic light-emitting layer EML may be formed by doping a dopant into the host. For example, in case that the light-emitting material layer emits blue light, the light-emitting material layer may be formed by doping a fluorescent dopant into at least one fluorescent host material selected from a group consisting of anthracene derivatives, pyrene derivatives, and perylene derivatives. For example, the blue fluoresent host material may include 4,4′-bis(2,2′-diphenylyinyl)-1,1′-biphenyl (DPVBi), 9,10-di-(2-naphtyl)anthracene (ADN), 2,5,8,11-tetra-t-butylperylene (TBADN), 2-tert-butyl-9,10-di(2-naphthyl)anthracene, 2-methyl-9,10-di(2-naphtyl) anthracene (MADN), and/or 2,2′,2″-(1,3,5-benzinetriyl)-tris(1-phenyl-1-H-benzimidazole) (TBPi). However, the present specification is not limited thereto.

In addition, 4,4′-bis(9-ethyl-3-carbazovinylene)-1,1′-biphenyl (BCzVBi) and/or diphenyl-[4-(2-[1,1;4,1]terphenyl-4-yl-vinyl)-phenyl]-amine (BD-1) may be used as the blue fluorescent dopant material.

In addition, in case that the light-emitting material layer emits green light, the light-emitting material layer may be formed by doping a phosphorescent dopant (e.g., dp Ir(acac), op Ir(acac), etc.), which is made of a metal complex, into a phosphorescent host material made of a carbazole-based compound.

In addition, in case that the light-emitting material layer emits red light, the light-emitting material layer may be formed by doping a phosphorescent dopant (e.g., Btp Ir(acac), etc.), which is made of a metal complex, into a phosphorescent host material made of a carbazole-based compound.

The electron transporting layer ETL is positioned between the organic light-emitting layer EML and the second electrode 143, and the electron injection layer EIL is positioned between the electron transporting layer ETL and the second electrode 143.

The electron transporting layer ETL may be a derivative made of oxadiazole, triazole, phenanthroline, benzoxazole, benzothiazole, benzimidazole, triazine, or the like. For example, the electron transporting layer ETL may be made of an electron transporting material such as tris-(8-hydroxyquinoline) aluminum (Alq3), 2-biphenyl-4-yl-5-(4-t-butylphenyl)-1,3,4-oxadiazole (PBD), Spiro-PBD, lithium quinolate (Liq), 2-[4-(9,10-Di-2-naphthalenyl-2-anthracenyl)phenyl]-1-phenyl-1H-benzimidazol, 3-(biphenyl-4-yl)-5-(4-tertbutylphenyl)-4-phenyl-4H-1,2,4-triazole (TAZ), 4,7-diphenyl-1,10-phenanthroline (Bphen), tris(phenylquinoxaline) (TPQ), and 1,3,5-tris(N-phenylbenzimiazole-2-yl) benzene (TPBI). However, the present specification is not limited thereto.

The electron transporting layer ETL may be formed by doping the above-mentioned organic material with metal such as alkaline metal and/or alkaline earth metal. The alkaline metal or alkaline earth metal may be added in a proportion of approximately 1 to 20 wt % on the basis of the above-mentioned organic compound. However, the present specification is not limited thereto. An alkaline metal component, which may be used as a dopant of the electron transporting layer ETL, may include alkaline metal, such as lithium (Li), sodium (Na), potassium (K), and cesium (Cs), and/or alkaline earth metal such as magnesium (Mg), strontium (Sr), barium (Ba), and radium (Ra). However, the present specification is not limited thereto. For example, in some embodiments, the electron transporting layer ETL may be configured as two or more layers instead of a single layer structure.

The electron injection layer EIL serves to facilitate the injection of electrons from the second electrode 143. The electron injection layer EIL may be excluded depending on the structure and characteristics of the display device.

An alkaline halide-based material, such as LiF, CsF, NaF, and BaF₂, and/or an organic metal-based material, such as lithium quinolate (Liq), lithium benzoate, and sodium stearate, may be used as a material of the electron injection layer EIL. However, the present specification is not limited thereto.

Meanwhile, the organic light-emitting element 140 according to the embodiment of the present specification may include the organic light-emitting layer EML made of aromatic hydrocarbon as a main material. In the case of the organic light-emitting layer EML, the organic light-emitting element is exposed to heat, which is generated when the organic light-emitting element is used, or exposed to an environment with a high temperature equal to or higher than a glass transition temperature of the light-emitting material. For this reason, molecular vibration, recrystallization, self-aggregation, and the like may occur, which may degrade the performance of the organic light-emitting element 140.

To suppress this situation, in the organic light-emitting element 140 according to the embodiment of the present specification, at least one binder 144, which includes a function group (or functional group) secondarily bonded to the organic light-emitting layer EML, may be disposed in the organic light-emitting part 142.

At least one binder 144 may be made of a non-conductive material and include an organic compound, for example. However, the present specification is not limited thereto.

The binder 144 according to the embodiment of the present specification may extend in a thickness direction of the organic light-emitting part 142. For example, the binder 144 may be disposed to extend in a vertical direction (i.e., Z direction) from the first electrode 141. However, the present specification is not limited thereto.

With reference to FIG. 4, at least one binder 144 may have a bottom surface adjoining the first electrode 141 and be disposed to penetrate all the hole auxiliary layers HIL and HTL, the organic light-emitting layer EML, and the electron auxiliary layers ETL and EIL.

In the display device 100 according to the embodiment of the present specification, the binder 144 may be disposed in the organic light-emitting part 142 disposed on the opening portion of the bank 135. For example, during the process of manufacturing the display device 100, the first electrode 141 and the bank 135 are disposed on the planarization layer 134, at least one binder 144 is disposed on the first electrode 141 exposed through the opening portion of the bank 135, the layers HIL. HTL, EML, ETL, and EIL of the organic light-emitting part 142 are sequentially deposited on the first electrode 141, and then the second electrode 143 is disposed to cover the binder 144 and the organic light-emitting part 142, such that the organic light-emitting element 140 may be implemented. For example, the plurality of binders 144 may be disposed by disposing an organic compound material on the first electrode 141 by means of a coating process and performing ashing at equal intervals based on a center of the subpixel. The process method is not limited thereto.

For example, as illustrated in FIG. 4, a first binder 144_C may be disposed at a center in the organic light-emitting part 142 when viewed in a horizontal direction (i.e., X direction). Further, a plurality of second binders 144_L1, 144_R1, 144_L2, and 144_R2 may be disposed in the organic light-emitting part 142, disposed symmetrically at two opposite sides based on the first binder 144_C, and spaced apart from one another. FIG. 4 illustrates an example in which second binders 144_L1 and 144_R1 are disposed at two opposite sides based on the first binder 144_C, and second binders 144_L2 and 144_R2 are disposed at two opposite sides based on the first binder 144_C and disposed outward of the second binders 144_L1 and 144_R1 (i.e., disposed adjacent to lateral portions of the banks 135). The number of second binders disposed at two opposite sides based on the first binder 144_C is not limited. FIG. 4 illustrates an example in which the plurality of binders 144_C, 144_L1, 144_R1, 144_L2, and 144_R2 are uniformly disposed so that distances d1 to d4 between the plurality of binders 144_C, 144_L1, 144_R1, 144_L2, and 144_R2 are equal. However, the present specification is not limited thereto.

As described above, at least one binder 144 is distributed and disposed in the organic light-emitting part 142, such that the layers of the organic light-emitting part 142 may be uniformly distributed and disposed by the binder 144 when the layers included in the organic light-emitting part 142 are deposited. Therefore, initial stress applied to the surface, on which the organic light-emitting part 142 is deposited, may be mitigated, such that excessive aggregation may be suppressed, and luminous properties may be improved.

In addition, at least one binder 144 may include at least one of functional groups, such as —OH, —F, and CONH, capable of hydrogen bonding that is a type of secondary bonding with aromatic hydrocarbon. However, the present specification is not limited thereto. In comparison with a case in which the binder 144 is not disposed in the organic light-emitting part 142, a molecular vibrational motion of the organic light-emitting layer EML may be suppressed, and the glass transition temperature (Tg) may be increased in case that the binder 144 including a functional group secondarily bonded to the organic light-emitting layer EML is disposed in the organic light-emitting part 142. Therefore, recrystallization of the organic light-emitting layer EML may be suppressed, thereby ensuring high thermal stability of the organic light-emitting element 140 and enabling a stable high-temperature operation.

In addition, the binder 144 made of a non-conductive material is distributed and disposed in the organic light-emitting part 142, such that the organic light-emitting layer EML may be divided into a plurality of portions. Therefore, it is possible to suppress a light leakage current (LLC) that may flow to the adjacent subpixel along the organic light-emitting part 142.

Various examples of the structure in which at least one binder 144 of the organic light-emitting element 140 according to an example embodiment of the present specification is disposed will be described with reference to FIGS. 5A to 5C.

FIG. 5A is a top plan view for explaining an example of an arrangement structure of the binder of the organic light-emitting element according to an example embodiment of the present specification.

With reference to FIG. 5A, in any one subpixel SP, the organic light-emitting part 142 may be disposed on the first electrode 141, and the plurality of binders 144 may be disposed in the organic light-emitting part 142 and spaced apart from one another in the first direction (i.e., Y direction) and the second direction (i.e., X direction) intersecting the first direction.

For example, in one subpixel SP, the plurality of binders 144 may be arranged in dot shapes in a plan view. However, the present specification is not limited thereto. In addition, FIG. 5A illustrates an example in which the binder 144 has a cylindrical shape having a circular horizontal cross-section. However, the shape of the horizontal cross-section of the binder 144 is not limited thereto. For example, the horizontal cross-section of the binder 144 may have a polygonal shape. The plurality of binders 144 are arranged in dot shapes as described above, thereby more efficiently ensuring the light-emitting area.

FIG. 5B is a top plan view for explaining another example of the arrangement structure of the binder of the organic light-emitting element according to an example embodiment of the present specification.

With reference to FIG. 5B, in any one subpixel SP, the organic light-emitting part 142 may be disposed on the first electrode 141, and the plurality of binders 144 may be disposed in the organic light-emitting part 142, integrally extend in the first direction (i.e., Y direction), and be spaced apart from one another in the second direction (i.e., X direction) intersecting the first direction. For example, the plurality of binders 144 each having a bar shape in a plan view may be arranged in stripe shapes in one subpixel SP. However, the present specification is not limited thereto. Therefore, in comparison with the example described with reference to FIG. 5A, the effect of suppressing initial excessive aggregation, ensuring thermal stability, and suppressing a leakage current may be further improved by the binder 144 when the organic light-emitting layer is deposited.

FIG. 5C is a top plan view for explaining still another example of the arrangement structure of the binder of the organic light-emitting element according to an example embodiment of the present specification.

With reference to FIG. 5C, in any one subpixel SP, the organic light-emitting part 142 is disposed on the first electrode 141. The binder 144 may be disposed in the organic light-emitting part 142 and include at least one row portion integrally extending in the first direction (i.e., Y direction), and at least one column portion integrally extending in the second direction (i.e., X direction) intersecting the first direction. For example, in one subpixel SP, the binder 144 may be arranged in a mesh shape in a plan view. However, the present specification is not limited thereto. Therefore, in comparison with the examples described with reference to FIGS. 5A and 5B, the effect of suppressing initial excessive aggregation, ensuring thermal stability, and suppressing a leakage current may be further improved by the binder 144 when the organic light-emitting layer is deposited.

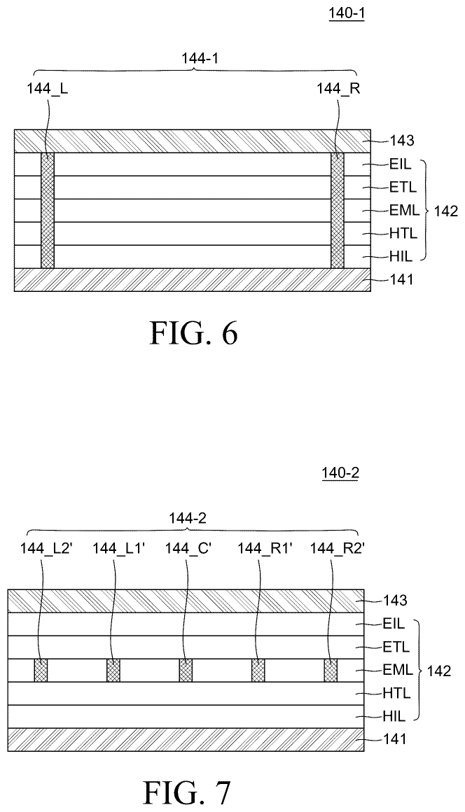

Hereinafter, structures of organic light-emitting elements of display devices according to various other example embodiments of the present specification will be described in detail with reference to FIGS. 6 to 8. The organic light-emitting elements of the display devices according to various example embodiments of the present specification described with reference to FIGS. 6 to 8 are substantially identical or similar in configuration to the organic light-emitting element 140 of the display device 100 according to the example embodiment of the present specification described above with reference to FIGS. 1 to 5C, except for the arrangement structures of the binders. Therefore, a repeated description may be omitted for convenience of description.

FIG. 6 is a cross-sectional view of an organic light-emitting element according to another example embodiment of the present specification.

With reference to FIG. 6, at least one binder 144-1, which is disposed in an edge area of the organic light-emitting part 142, may be disposed in an organic light-emitting element 140-1 according to another example embodiment of the present specification. For example, a first binder 144_L may be disposed in one side edge area of the organic light-emitting part 142, and a second binder 144_R may be disposed in the other side edge area of the organic light-emitting part 142. In addition, the binder may not be disposed in an area excluding the edge area of the organic light-emitting element 140-1.

For example, two opposite side edge areas of the organic light-emitting part 142 in which the first binder 144_L and the second binder 144_R are disposed may be areas adjacent to the lateral portion of the bank 135. Further, as illustrated in FIG. 6, the first binder 144_L and the second binder 144_R may have bottom surfaces adjoining the first electrode 141 and be disposed to penetrate all the hole auxiliary layers HIL and HTL, the organic light-emitting layer EML, and the electron auxiliary layers ETL and EIL. Therefore, it is possible to suppress the light leakage current (LLC) that may flow to the adjacent subpixel along the organic light-emitting part 142. Further, an area occupied by the binder 144-1 in the organic light-emitting part 142 may be minimized or reduced, thereby ensuring the light-emitting area of the organic light-emitting element 140-1 and improving the luminous efficiency.

FIG. 7 is a cross-sectional view of an organic light-emitting element according to still another example embodiment of the present specification.

With reference to FIG. 7, in an organic light-emitting element 140-2 according to still another example embodiment of the present specification, at least one binder 144-2 may be disposed only in the organic light-emitting layer EML of the organic light-emitting part 142.

For example, as illustrated in FIG. 7, at least one binder 144-2 may have a bottom surface adjoining a top surface of the hole transporting layer HTL, penetrate the organic light-emitting layer EML, and have a top surface adjoining a bottom surface of the electron transporting layer ETL.

For example, during the process of manufacturing the display device 100, the first electrode 141 and the bank 135 are disposed on the planarization layer 134, the hole auxiliary layers HIL and HTL are deposited on the first electrode 141 exposed through the opening portion of the bank 135, at least one binder 144-2 is disposed on the hole auxiliary layers HIL and HTL, the remaining layers EML, ETL, and EIL of the organic light-emitting part 142 are sequentially deposited on the hole auxiliary layers HIL and HTL, and then the second electrode 143 is disposed to cover the binder 144-2 and the organic light-emitting part 142, such that the organic light-emitting element 140-2 may be implemented.

For example, as illustrated in FIG. 7, a first binder 144_C′ may be disposed at a center in the organic light-emitting layer EML when viewed in the horizontal direction. Further, a plurality of second binders 144_L1′, 144_R1′, 144_L2′, and 144_R2′ may be disposed in the organic light-emitting layer EML, disposed symmetrically at two opposite sides based on the first binder 144_C′, and spaced apart from one another. FIG. 7 illustrates an example in which second binders 144_L1′ and 144_R1′ are disposed at two opposite sides based on the first binder 144_C′, and second binders 144_L2′ and 144_R2′ are disposed at two opposite sides based on the first binder 144_C′ and disposed outward of the second binders 144_L1′ and 144_R1′ (i.e., disposed adjacent to lateral portions of the banks 135). The number of second binders disposed at two opposite sides based on the first binder 144_C′ is not limited.

As described above, at least one binder 144-2 is distributed and disposed in the organic light-emitting layer EML, such that the layers of the organic light-emitting part 142 may be uniformly distributed by the binder 144-2 when the layers included in the organic light-emitting part 142 are deposited. Therefore, initial stress applied to the surface, on which the organic light-emitting part 142 is deposited, may be mitigated, such that excessive aggregation may be suppressed, and luminous properties may be improved.

Further, it is possible to ensure the effect achieved by the binder with respect to the organic light-emitting layer EML vulnerable to degradation, minimize or reduce resistance in the organic light-emitting part 142 caused by the binder made of a non-conductive material, thereby improving luminous efficiency.

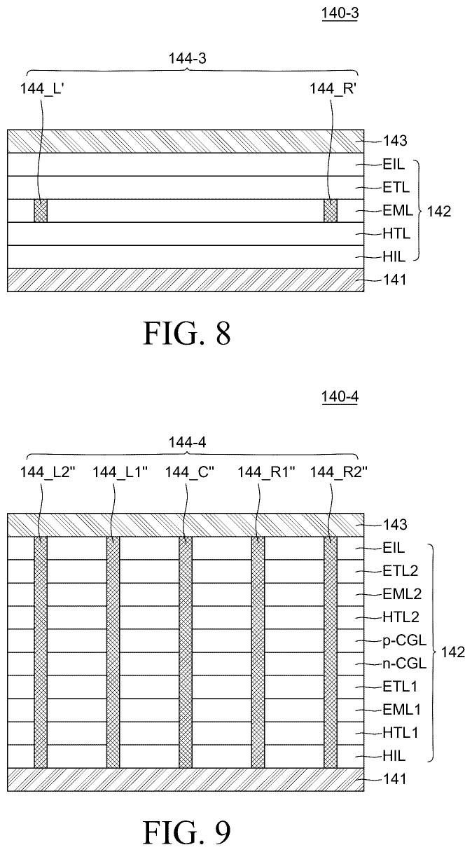

FIG. 8 is a cross-sectional view of an organic light-emitting element according to yet another example embodiment of the present specification.

With reference to FIG. 8, at least one binder 144-3 may be disposed in an edge area in an organic light-emitting element 140-3 according to yet another embodiment of the present specification. In this case, at least one binder 144-3 may be disposed only in the organic light-emitting layer EML of the organic light-emitting part 142.

For example, in the organic light-emitting element 140-3, a first binder 144_L′ may be disposed in one side edge area of the organic light-emitting part 142, and a second binder 144_R′ may be disposed in the other side edge area of the organic light-emitting part 142. In addition, the binder may not be disposed in an area excluding the edge area of the organic light-emitting element 140-3.

For example, two opposite side edge areas of the organic light-emitting part 142 in which the first binder 144_L′ and the second binder 144_R′ are disposed may be areas adjacent to the lateral portion of the bank 135. Further, as illustrated in FIG. 8, the first binder 144_L′ and the second binder 144_R′ may have bottom surfaces adjoining the top surface of the hole transporting layer HTL, penetrate the organic light-emitting layer EML, and have top surfaces adjoining the bottom surface of the electron transporting layer ETL.

Therefore, it is possible to suppress the light leakage current (LLC) that may flow to the adjacent subpixel along the organic light-emitting part 142. Further, it is possible to ensure the light-emitting area of the organic light-emitting element 140-3 and improve the luminous efficiency. In addition, it is possible to ensure the effect achieved by the binder with respect to the organic light-emitting layer EML vulnerable to degradation, minimize or reduce resistance in the organic light-emitting part 142 caused by the binder made of a non-conductive material, thereby improving luminous efficiency.

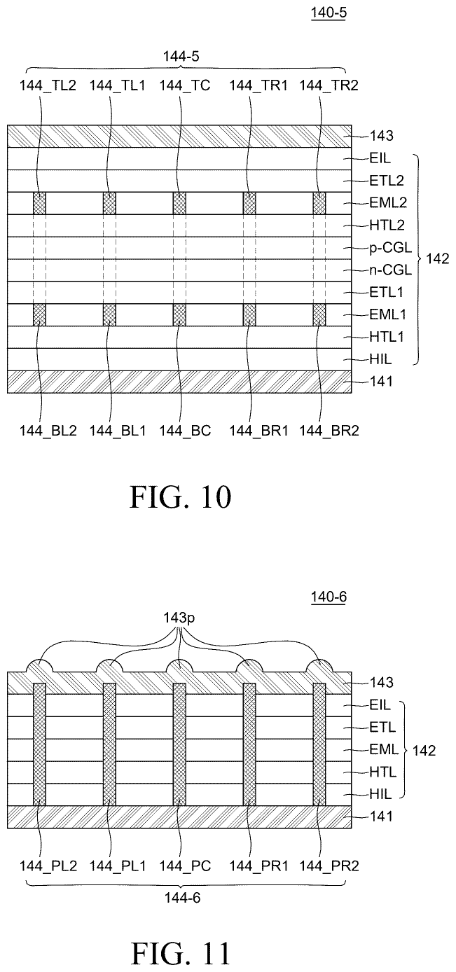

Hereinafter, structures of organic light-emitting elements of display devices according to various other example embodiments of the present specification will be described in detail with reference to FIGS. 9 and 10. The organic light-emitting elements according to various example embodiments of the present specification described with reference to FIGS. 9 and 10 are substantially identical or similar in configuration to various examples of the organic light-emitting element of the display device 100 according to example embodiments of the present specification described above with reference to FIGS. 4 to 8, except for the structures of the organic light-emitting parts. Therefore, a repeated description may be omitted for convenience of description.

The example in which the organic light-emitting element has the single stack structure including one organic light-emitting part has been described above with reference to FIGS. 4 to 8. In contrast, an example in which the organic light-emitting element has a tandem structure configured by stacking a plurality of stacks of two or more organic light-emitting parts will be described with reference to FIGS. 9 and 10.

FIG. 9 is a cross-sectional view of an organic light-emitting element according to still yet another example embodiment of the present specification.

With reference to FIG. 9, an organic light-emitting part 142 of an organic light-emitting element 140-4 according to still yet another example embodiment of the present specification may include a first organic light-emitting part, a second organic light-emitting part, and a charge generating layer disposed between the first organic light-emitting part and the second organic light-emitting part.

For example, the first organic light-emitting part of the organic light-emitting element 140-4 includes a first hole auxiliary layer including a hole injection layer HIL and a first hole transporting layer HTL1, a first organic light-emitting layer EML1 including a light-emitting material layer, and a first electron auxiliary layer including a first electron transporting layer ETL1. However, the present specification is not limited thereto. Further, the second organic light-emitting part of the organic light-emitting element 140-4 includes a second hole auxiliary layer including a second hole transporting layer HTL2, a second organic light-emitting layer EML2 including a light-emitting material layer, and a second electron auxiliary layer including a second electron transporting layer ETL1 and an electron injection layer EIL. However, the present specification is not limited thereto. For example, the first organic light-emitting layer EML1 and the second organic light-emitting layer EML2 may include the light-emitting material layers configured to emit light beams with the same color. However, the present specification is not limited thereto. For example, the first organic light-emitting layer EML1 and the second organic light-emitting layer EML2 may include the light-emitting material layers configured to emit light beams with different colors. In addition, FIG. 9 illustrates an example in which the organic light-emitting element 140-4 has a structure in which the first organic light-emitting part and the second organic light-emitting part are stacked. However, the present specification is not limited thereto. For example, the organic light-emitting element 140-4 may have a tandem structure in which two or more organic light-emitting parts are stacked. At least some of the two or more organic light-emitting parts may include organic light-emitting layers configured to emit light beams with the same color or different colors.

In addition, to obtain the improved light emission effect by connecting the plurality of organic light-emitting parts, a charge generating layer (CGL) may be disposed between the first organic light-emitting part and the second organic light-emitting part of the organic light-emitting element 140-4. As illustrated in FIG. 9, charge generating layers n-CGL and p-CGL may be disposed above the first electron transporting layer ETL1 of the first organic light-emitting part, and the second hole transporting layer HTL2 of the second organic light-emitting part may be disposed above the charge generating layers n-CGL and p-CGL. However, the present specification is not limited thereto. For example, only one n-type charge generating layer n-CGL or p-type charge generating layer p-CGL may be provided as the charge generating layer.

For example, the n-type charge generating layer n-CGL may be configured as an organic layer made by doping a material of the hole injection layer with F4-TCNQ (2,3,5,6-tetrafluoro-7,7,8,8-tetracyano-quinodimethane), FeCl, FeF, SbCl, and the like. For example, the p-type charge generating layer p-CGL may be configured as an organic layer made by doping a material of the electron transporting layer with alkaline metal, such as lithium (Li), sodium (Na), potassium (K), or cesium (Cs), or alkaline earth metal such as magnesium (Mg), strontium (Sr), barium (Ba), or radium (Ra).

As illustrated in FIG. 9, in the organic light-emitting element 140-4 according to still yet another example embodiment of the present specification, at least one binder 144-4 may have a bottom surface adjoining the first electrode 141 and be disposed to penetrate all the first hole auxiliary layers HIL and HTL1, the first organic light-emitting layer EML1, a first electron auxiliary layer ETL11, the charge generating layers n-CGL and p-CGL, a second hole auxiliary layer HTL2, the second organic light-emitting layer EML2, and the second electron auxiliary layers ETL2 and EIL.

For example, a first binder 144_C″ may be disposed at a center in the organic light-emitting part 142 when viewed in the horizontal direction. Further, a plurality of second binders 144_L1″, 144_R1″, 144_L2″, and 144_R2″ may be disposed in the organic light-emitting part 142, disposed symmetrically at two opposite sides based on the first binder 144_C″, and spaced apart from one another. FIG. 9 illustrates an example in which second binders 144_L1″ and 144_R1″ are disposed at two opposite sides based on the first binder 144_C″, and second binders 144_L2″ and 144_R2″ are disposed at two opposite sides based on the first binder 144_C″ and disposed outward of the second binders 144_L1″ and 144_R1″ (i.e., disposed adjacent to lateral portions of the banks 135). The number of second binders disposed at two opposite sides based on the first binder 144_C″ is not limited.

In another example, like the structure described above with reference to FIG. 6, in the organic light-emitting element 140-4, at least one binder 144-4 may be disposed in an edge area of the organic light-emitting part 142, and the binder may not be disposed in an area excluding the edge area of the organic light-emitting element 140-4.

FIG. 10 is a cross-sectional view of an organic light-emitting element according to a further example embodiment of the present specification.

With reference to FIG. 10, an organic light-emitting part 412 of an organic light-emitting element 140-5 according to the further embodiment of the present specification may include a first organic light-emitting part, a second organic light-emitting part, and a charge generating layer disposed between the first organic light-emitting part and the second organic light-emitting part.

In the organic light-emitting element 140-5 according to the further embodiment of the present specification, at least one binder 144-5 may be disposed only in the organic light-emitting layers of the first organic light-emitting part and the second organic light-emitting part.

For example, at least one binder 144-2 may include first binder parts disposed in a first organic light-emitting layer of the first organic light-emitting part, and second binder parts disposed in a second organic light-emitting layer of the second organic light-emitting part.

With reference to FIG. 10, first binder parts 144_BL2, 144_BL1, 144_BC, 144_BR1, and 144_BR2 may have bottom surfaces adjoining the top surface of the first hole transporting layer HTL1, penetrate the first organic light-emitting layer EML1, and have top surfaces adjoining the bottom surface of the first electron transporting layer ETL1. Second binder parts 144_TL2, 144_TL1, 144_TC, 144_TR1, and 144_TR2 may have bottom surfaces adjoining the top surface of the second hole transporting layer HTL2, penetrate the second organic light-emitting layer EML2, and have top surfaces adjoining a bottom surface of a second electron transporting layer ETL2. The first binder parts 144_BL2, 144_BL1, 144_BC, 144_BR1, and 144_BR2 may be referred to as lower binders, and the second binder parts 144_TL2, 144_TL1, 144_TC, 144_TR1, and 144_TR2 maybe referred to as upper binders.

For example, among the lower binders, a first lower binder 144_BC may be disposed at a center in the first organic light-emitting layer EML1 when viewed in the horizontal direction. Further, among the lower binders, a plurality of second lower binders 144_BL1, 144_BR1, 144_BL2, and 144_BR2 may be disposed in the first organic light-emitting layer EML, disposed symmetrically at two opposite sides based on the first lower binder 144_BC, and spaced apart from one another. FIG. 10 illustrates an example in which second lower binders 144_BL1 and 144_BR1 are disposed at two opposite sides based on the first lower binder 144_BC, and second lower binders 144_BL2 and 144_BR2 are disposed at two opposite sides based on the first lower binder 144_BC and disposed outward of the second lower binders 144_BL1 and 144_BR1 (i.e., disposed adjacent to lateral portions of the banks 135). The number of second lower binders disposed at two opposite sides based on the first lower binder 144_BC is not limited.

In addition, among the upper binders, a first upper binder 144_TC may be disposed at a center in the second organic light-emitting layer EML2 when viewed in the horizontal direction. Further, among the upper binders, a plurality of second upper binders 144_TL1, 144_TR1, 144_TL2, and 144_TR2 may be disposed in the second organic light-emitting layer EML2, disposed symmetrically at two opposite sides based on the first upper binder 144_TC, and spaced apart from one another. FIG. 10 illustrates an example in which second upper binders 144_TL1 and 144_TR1 are disposed at two opposite sides based on the first upper binder 144_TC, and second upper binders 144_TL2 and 144_TR2 disposed at two opposite sides based on the first upper binder 144_TC and disposed outward of the second upper binders 144_TL1 and 144_TR1 (i.e., disposed adjacent to lateral portions of the banks 135). The number of second upper binders disposed at two opposite sides based on the first upper binder 144_TC is not limited.

In another example, like the structure described above with reference to FIG. 6, in the organic light-emitting element 140-5, at least one binder 144-5 may be disposed in an edge area of the organic light-emitting part 142, and the binder may not be disposed in an area excluding the edge area of the organic light-emitting element 140-5.

Hereinafter, a structure of an organic light-emitting element of a display device according to another further example embodiment of the present specification will be described in detail with reference to FIG. 11. The organic light-emitting element according to another further example embodiment of the present specification described with reference to FIG. 11 is substantially identical or similar in configuration to various examples of the organic light-emitting elements according to the example embodiments of the present specification described above with reference to FIGS. 4 to 10, except for partial structures of the binder and the second electrode. Therefore, a repeated description may be omitted for convenience of description.

FIG. 11 is a cross-sectional view of the organic light-emitting element according to another further example embodiment of the present specification.

With reference to FIG. 11, in an organic light-emitting element 140-6 according to another further example embodiment of the present specification, at least one binder 144-6 is disposed in the organic light-emitting part 142, and one end of the binder 144-6 further protrudes toward the second electrode 143 than the organic light-emitting part 142. With at least one binder 144-6, a top surface of the second electrode 143 may have a non-flat structure. A height of at least one binder 144-6 from the first electrode 141 may be larger than a height of the electron auxiliary layers ETL and EIL from the first electrode 141. In this case, an area in which the top surface of the second electrode 143 overlaps at least one binder 144-6 and an area in which the top surface of the second electrode 143 does not overlap at least one binder 144-6 may have different heights.

For example, as illustrated in FIG. 11, the top surface of the second electrode 143 may have a convex portion 143p in an area that overlaps one protruding end of the binder 144-6. Therefore, a path of a part of light emitted from the organic light-emitting part 142 may be changed by convex areas of the plurality of second electrodes 143, thereby improving light extraction efficiency. For example, a propagation path of the light emitted from the organic light-emitting part 142 may be guided to a light emergent surface, and the light, which is totally reflected in the organic light-emitting part 142, may be emitted toward the light emergent surface, thereby suppressing or minimizing a deterioration in light extraction efficiency caused by light trapped in the organic light-emitting part 142.

With reference to FIG. 11, in the organic light-emitting element 140-6 according to another further example embodiment of the present specification, at least one binder 144-6 may have the bottom surface adjoining the first electrode 141, penetrate all the hole auxiliary layers HIL and HTL, the organic light-emitting layer EML, and the electron auxiliary layers ETL and EIL, and have the top surface adjoining the second electrode 143 and further protruding than the electron auxiliary layers ETL and EIL.

For example, a first binder 144_PC may be disposed at a center in the organic light-emitting part 142 when viewed in the horizontal direction. Further, a plurality of second binders 144_PL1, 144_PR1, 144_PL2, and 144_PR2 may be disposed in the organic light-emitting part 142, disposed symmetrically at two opposite sides based on the first binder 144_PC, and spaced apart from one another. FIG. 10 illustrates an example in which second binders 144_PL1 and 144_PR1 are disposed at two opposite sides based on the first binder 144_PC, and second binders 144_PL2 and 144_PR2 are disposed at two opposite sides based on the first binder 144_PC and disposed outward of the second binders 144_PL1 and 144_PR1 (i.e., disposed adjacent to lateral portions of the banks 135). The number of second binders disposed at two opposite sides based on the first binder 144_PC is not limited.

In another example, like the structure described above with reference to FIG. 6, in the organic light-emitting element 140-6, at least one binder 144-6 may be disposed in an edge area of the organic light-emitting part 142, and the binder may not be disposed in an area excluding the edge area of the organic light-emitting element 140-6.

In still another example, like the structure described above with reference to FIGS. 9 and 10, the organic light-emitting part 412 of the organic light-emitting element 140-6 may include the first organic light-emitting part, the second organic light-emitting part, and the charge generating layer disposed between the first organic light-emitting part and the second organic light-emitting part.

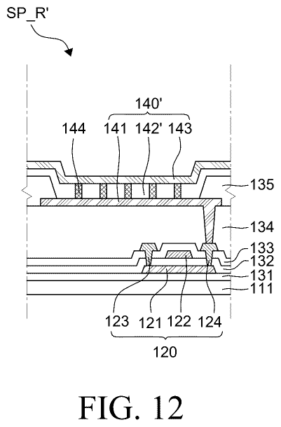

Hereinafter, a display device according to another example embodiment of the present specification will be described with reference to FIG. 12. The display device according to another example embodiment of the present specification described with reference to FIG. 12 is substantially identical or similar in configuration to the display device according to the example embodiments of the present specification described above with reference to FIGS. 1 to 11, except for a partial structure of an organic light-emitting element 140′. Therefore, a repeated description may be omitted for convenience of description.

FIG. 12 is a cross-sectional view of a subpixel of a display device according to another example embodiment of the present specification.

FIG. 12 illustrates a cross-section of a partial area of the display panel according to another example embodiment of the present specification display device and illustrates an example of a structure of a subpixel SP_R′ identical to the subpixel SP_R configured to emit red light among the plurality of subpixels SP_R, SP_G, and SP_B included in one pixel P described above with reference to FIGS. 1 to 3. However, the type of subpixel is not limited thereto.

With reference to FIG. 12, in the organic light-emitting element 140′ according to another example embodiment of the present specification, the organic light-emitting part 142′ may fill the opening portion of the bank 135 and be disposed to cover the lateral portion and the upper portion of the bank 135, and the second electrode 143 may be disposed on the organic light-emitting part 142′. In addition, at least one binder 144 may be disposed on the opening portion of the bank 135 and disposed in the organic light-emitting part 142′.

For example, at least one binder 144 may have a bottom surface adjoining the first electrode 141, penetrate the hole auxiliary layer, the organic light-emitting layer, and the electron auxiliary layer, and have a top surface adjoining the second electrode 143.

At least one binder 144 may be disposed in at least one of the two opposite side edge areas of the organic light-emitting part 142′ and disposed in an area adjacent to the lateral portion of the bank 135. Therefore, even with the structure in which the organic light-emitting part 142′ is disposed above the bank 135, it is possible to suppress the light leakage current (LLC) that may flow to the adjacent subpixel along the organic light-emitting part 142. Further, it is possible to ensure the light-emitting area of the organic light-emitting element 140-1 and improve the luminous efficiency.

Example embodiments of the present disclosure can also be described as follows:

According to an aspect of the present disclosure, there is provided an organic light-emitting element. The organic light-emitting element includes a substrate. The organic light-emitting element further includes a first electrode disposed on the substrate. The organic light-emitting element further includes a hole auxiliary layer disposed on the first electrode. The organic light-emitting element further includes at least one organic light-emitting layer disposed on the hole auxiliary layer. The organic light-emitting element further includes an electron auxiliary layer disposed on the organic light-emitting layer. The organic light-emitting element further includes at least one binder disposed in the organic light-emitting layer and comprising a functional group secondarily bonded to the organic light-emitting layer. The organic light-emitting element further includes a second electrode disposed on the electron auxiliary layer.

The at least one binder may be disposed in a vertical direction from the first electrode.

The at least one binder may have a bottom surface adjoining the first electrode and may penetrate the hole auxiliary layer, the organic light-emitting layer, and the electron auxiliary layer.

The at least one binder may include a first binder disposed at a center of the organic light-emitting layer.

The at least one binder may further include a plurality of second binders disposed symmetrically at two opposite sides based on the first binder and spaced apart from one another.

A height of the at least one binder from the first electrode may be larger than a height of the electron auxiliary layer from the first electrode.

An area in which a top surface of the second electrode overlaps the at least one binder and an area in which the top surface of the second electrode does not overlap the at least one binder may have different heights.

The at least one binder may include a first binder disposed in one side edge area of the organic light-emitting layer, and a second binder disposed in the other side edge area of the organic light-emitting layer.

The at least one binder may have a bottom surface adjoining a top surface of the hole auxiliary layer, penetrate the organic light-emitting layer, and have a top surface adjoining a bottom surface of the electron auxiliary layer.

The at least one binder may include a first binder disposed at a center of the organic light-emitting layer.

The at least one binder may further include a plurality of second binders disposed symmetrically at two opposite sides based on the first binder and spaced apart from one another.

The at least one binder may include a first binder disposed in one side edge area of the organic light-emitting layer, and a second binder disposed in the other side edge area of the organic light-emitting layer.

The at least one binder may include a plurality of first binders disposed to be spaced apart from one another in a first direction and a second direction intersecting the first direction in a plan view.

The at least one binder may include a plurality of first binders integrally extending in a first direction and spaced apart from one another in a second direction intersecting the first direction in a plan view.

The at least one binder may be disposed in a mesh shape in a plan view.

According to another aspect of the present disclosure, there is provided a display device. The display device includes a substrate including a display area. The display area includes a plurality of subpixels. The display device further includes an organic light-emitting element disposed on the substrate in the display area and including a first electrode, an organic light-emitting part disposed on the first electrode, and a second electrode disposed on the organic light-emitting part. The display device further includes a bank disposed on the substrate and including an opening configured to expose the first electrode. The display device further includes at least one binder disposed in the opening and including a functional group secondarily bonded to a light-emitting layer of the organic light-emitting part.

The organic light-emitting part may include a hole auxiliary layer disposed on the first electrode, at least one organic light-emitting layer disposed on the hole auxiliary layer, and an electron auxiliary layer disposed on the organic light-emitting layer. The at least one binder may have a bottom surface adjoining the first electrode and have a side surface adjoining the hole auxiliary layer, the organic light-emitting layer, and the electron auxiliary layer.

The organic light-emitting part may include a hole auxiliary layer disposed on the first electrode, at least one organic light-emitting layer disposed on the hole auxiliary layer, and an electron auxiliary layer disposed on the organic light-emitting layer. The at least one binder may have a bottom surface adjoining a top surface of the hole auxiliary layer, have a side surface adjoining the organic light-emitting layer, and have a top surface adjoining a bottom surface of the electron auxiliary layer.

The organic light-emitting part may fill the opening of the bank and may cover a lateral portion and an upper portion of the bank.

The at least one binder may include a non-conductive material and be disposed at an edge adjacent to the lateral portion of the bank in the opening.

Although example embodiments of the present disclosure have been described in detail with reference to the accompanying drawings, the present disclosure is not limited thereto and may be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure.

What is claimed is:

1. An organic light-emitting element, comprising:
a substrate;
a first electrode disposed on the substrate;
a hole auxiliary layer disposed on the first electrode;
at least one organic light-emitting layer disposed on the hole auxiliary layer;
an electron auxiliary layer disposed on the organic light-emitting layer;
at least one binder disposed in the organic light-emitting layer and including a functional group secondarily bonded to the organic light-emitting layer; and
a second electrode disposed on the electron auxiliary layer.

2. The organic light-emitting element of claim 1, wherein the at least one binder is disposed to extend in a vertical direction from the first electrode.

3. The organic light-emitting element of claim 1, wherein the at least one binder has a bottom surface adjoining the first electrode and penetrates the hole auxiliary layer, the organic light-emitting layer, and the electron auxiliary layer.

4. The organic light-emitting element of claim 3, wherein the at least one binder includes a first binder disposed at a center of the organic light-emitting layer.

5. The organic light-emitting element of claim 4, wherein the at least one binder further includes a plurality of second binders disposed symmetrically at two opposite sides based on the first binder and spaced apart from one another.

6. The organic light-emitting element of claim 5, wherein a height of the at least one binder from the first electrode is larger than a height of the electron auxiliary layer from the first electrode, and
wherein an area in which a top surface of the second electrode overlaps the at least one binder and an area in which the top surface of the second electrode does not overlap the at least one binder have different heights.

7. The organic light-emitting element of claim 6, wherein the top surface of the second electrode has a convex portion in the area that overlaps the at least one binder.

8. The organic light-emitting element of claim 3, wherein the at least one binder includes:
a first binder disposed in one side edge area of the organic light-emitting layer; and
a second binder disposed in the other side edge area of the organic light-emitting layer.

9. The organic light-emitting element of claim 1, wherein the at least one binder has a bottom surface adjoining a top surface of the hole auxiliary layer, penetrates the organic light-emitting layer, and has a top surface adjoining a bottom surface of the electron auxiliary layer, and
wherein the at least one binder includes a first binder disposed at a center of the organic light-emitting layer.

10. The organic light-emitting element of claim 1, wherein the at least one binder has a bottom surface adjoining a top surface of the hole auxiliary layer, penetrates the organic light-emitting layer, and has a top surface adjoining a bottom surface of the electron auxiliary layer, and
wherein the at least one binder includes a first binder and a plurality of second binders disposed symmetrically at two opposite sides based on the first binder and spaced apart from one another.

11. The organic light-emitting element of claim 1, wherein the at least one binder has a bottom surface adjoining a top surface of the hole auxiliary layer, penetrates the organic light-emitting layer, and has a top surface adjoining a bottom surface of the electron auxiliary layer, and
wherein the at least one binder includes:
a first binder disposed in one side edge area of the organic light-emitting layer; and
a second binder disposed in the other side edge area of the organic light-emitting layer.

12. The organic light-emitting element of claim 1, wherein the at least one binder includes a plurality of first binders disposed to be spaced apart from one another in a first direction and a second direction intersecting the first direction in a plan view.

13. The organic light-emitting element of claim 1, wherein the at least one binder includes a plurality of first binders integrally extending in a first direction and spaced apart from one another in a second direction intersecting the first direction in a plan view.

14. The organic light-emitting element of claim 1, wherein the at least one binder is disposed in a mesh shape in a plan view.

15. A display device, comprising:
a substrate including a display area, the display area including a plurality of subpixels;
an organic light-emitting element disposed on the substrate in the display area and including a first electrode, an organic light-emitting part disposed on the first electrode, and a second electrode disposed on the organic light-emitting part;
a bank disposed on the substrate and including an opening configured to expose the first electrode; and
at least one binder disposed in the opening and including a functional group secondarily bonded to a light-emitting layer of the organic light-emitting part.

16. The display device of claim 15, wherein the organic light-emitting part includes:
a hole auxiliary layer disposed on the first electrode;
at least one organic light-emitting layer disposed on the hole auxiliary layer; and
an electron auxiliary layer disposed on the organic light-emitting layer, and
wherein the at least one binder has a bottom surface adjoining the first electrode and has a side surface adjoining the hole auxiliary layer, the organic light-emitting layer, and the electron auxiliary layer.

17. The display device of claim 15, wherein the organic light-emitting part includes:
a hole auxiliary layer disposed on the first electrode;
at least one organic light-emitting layer disposed on the hole auxiliary layer; and
an electron auxiliary layer disposed on the organic light-emitting layer, and
wherein the at least one binder has a bottom surface adjoining a top surface of the hole auxiliary layer, has a side surface adjoining the organic light-emitting layer, and has a top surface adjoining a bottom surface of the electron auxiliary layer.

18. The display device of claim 15, wherein the organic light-emitting part fills the opening of the bank and covers a lateral portion and an upper portion of the bank, wherein the at least one binder includes a non-conductive material and is disposed at an edge adjacent to the lateral portion of the bank in the opening.

19. The display device of claim 15, wherein a plurality of organic light-emitting parts are stacked between the first electrode and the second electrode,
wherein the display device further comprises a charge generating layer disposed between adjacent organic light-emitting parts among the plurality of organic light-emitting parts, and
wherein the at least one binder has a bottom surface adjoining the first electrode and penetrates all layers of the plurality of organic light-emitting parts and the charge generating layer.

20. The display device of claim 15, wherein a plurality of organic light-emitting parts are stacked between the first electrode and the second electrode,
wherein the display device further comprises a charge generating layer disposed between adjacent organic light-emitting parts among the plurality of organic light-emitting parts,
wherein the plurality of organic light-emitting parts each includes:
a hole auxiliary layer;
at least one organic light-emitting layer disposed on the hole auxiliary layer; and
an electron auxiliary layer disposed on the organic light-emitting layer, and
wherein the at least one binder the at least one binder is only disposed in the organic light-emitting layers of the plurality of organic light-emitting parts, penetrates the organic light-emitting layers, but does not penetrate other layers of the plurality of organic light-emitting parts.
